(19) United States
(12) Patent Application Publication
(10) Pub. No.: US 2008/0012136 A1
(43) Pub. Date: Jan. 17, 2008

(54) Metal Interconnection Structure of Semiconductor Device and Method for Manufacturing the Same

(76) Inventor: Jong Taek HWANG, Cheongju-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/777,115

(22) Filed: Jul. 12, 2007

(30) Foreign Application Priority Data
Jul. 12, 2006 (KR) 10-2006-0065402

(51) Int. Cl. H01L 23/52; H01L 21/441

(52) U.S. Cl. 257/753; 438/654; 257/E23.011; 257/E21.477

(57) ABSTRACT

Disclosed are a metal interconnection structure of a semiconductor device and a method for manufacturing the same. The structure includes an upper interlayer dielectric layer pattern including fluorine (F), an upper metal interconnection in the upper interlayer dielectric layer pattern and connecting with a lower metal interconnection formed in a lower interlayer dielectric layer pattern. The lower interlayer dielectric layer pattern can include a barrier pattern provided below the upper interlayer dielectric layer pattern to inhibit diffusion of F, an adhesion layer pattern below the barrier layer pattern, and a silicon-oxy-carbide (SiOC) layer pattern below the adhesion layer pattern. In order to inhibit F from penetrating into a neighboring interlayer dielectric layer, the barrier layer can include boron (B), which can combine with F, thereby inhibiting diffusion of the F. Accordingly, the increase of the dielectric constant of an SiOC layer due to diffusion of F is inhibited.

### CROSS-REFERENCE TO RELATED APPLICATION

The present application claims the benefit under 35 U.S.C. § 119 of Korean Patent Application No. 10-2006-0065402, filed Jul. 12, 2006, which is hereby incorporated by reference in its entirety.

### BACKGROUND

As semiconductor manufacturing technology develops, semiconductor devices become highly integrated. For this reason, the design rule minimum sizes of semiconductor devices becomes smaller. Accordingly, the interval spacing of multi-layer metal interconnections of semiconductor devices is becoming narrower.

When a silicon oxide layer is interposed between the multi-layer metal interconnections having the narrow interval spacing as an interlayer dielectric layer, signals applied to the multi-layer metal interconnections may be delayed or distorted.

In order to overcome the above problem, a silicon-oxy-carbide (SiOC) layer having a low dielectric constant may be provided as a lower interlayer dielectric layer, and an upper interlayer dielectric layer having a low dielectric constant is formed on the lower interlayer dielectric layer by adding fluorine (F) to the lower dielectric layer. A capping layer may be interposed between the lower interlayer dielectric layer and the upper interlayer dielectric layer.

However, since the fluorine (F) added to the related upper interlayer dielectric layer has a high migration property, the fluorine (F) may move to the silicon-oxy-carbide (SiOC) layer from the upper interlayer dielectric layer through a pin hole formed in the capping layer. The fluorine (F) having been moved to the silicon-oxy-carbide (SiOC) layer chemically reacts with silicon-oxy-carbide (SiOC) of the silicon-oxy-carbide (SiOC) layer, thereby forming fluorinated silicon oxide (SiOF).

Since the fluorinated silicon oxide (SiOF) included in the lower interlayer dielectric layer has a dielectric constant higher than that of the silicon-oxy-carbide (SiOC), signals applied to metal interconnections disposed on the lower interlayer dielectric layer having the fluorinated silicon oxide (SiOF) may be delayed or distorted. In addition, if the metal interconnection includes copper (Cu), the silicon-oxy-carbide (SiOC) included in the lower interlayer dielectric layer exhibits inferior adhesive property relative to the copper (Cu), so that the lower interlayer dielectric layer and the metal interconnection including the copper (Cu) may become separated or delaminated from each other.

### BRIEF SUMMARY

Embodiments of the present invention provide a metal interconnection structure of a semiconductor device and a method of manufacturing the same.

In one aspect of an embodiment, a metal interconnection structure of a semiconductor device can include an upper interlayer dielectric layer pattern including fluorine (F), an upper metal interconnection extending through the upper interlayer dielectric layer pattern, a lower interlayer dielectric layer pattern including a barrier pattern which is provided at a lower portion of the upper interlayer dielectric layer pattern to prevent fluorine (F) from being diffused, an adhesion layer pattern in a lower portion of the barrier layer pattern, and a silicon-oxy-carbide (SiOC) layer pattern in a lower portion of the adhesion layer pattern, and a lower metal interconnection extending through the lower interlayer dielectric layer pattern to connect with the upper metal interconnection.

In another aspect of an embodiment, there is provided a method for manufacturing a metal interconnection structure of a semiconductor device. In the method for manufacturing the metal interconnection structure of the semiconductor device according to one embodiment, a lower interlayer dielectric layer is formed by sequentially forming a lower capping layer covering a lower structure, a silicon-oxy-carbide (SiOC) layer pattern on the lower capping layer, an adhesion layer on the silicon-oxy-carbide (SiOC) layer, and a barrier layer on the adhesion layer by implanting boron onto a surface of the adhesion layer. A lower metal interconnection extends by passing through the lower interlayer dielectric layer. An upper capping layer is formed on a top surface of the barrier layer and an upper interlayer dielectric layer including fluorine (F) is formed on the upper capping layer. An upper metal interconnection extends by passing through the upper interlayer dielectric layer to electrically connect with the lower metal interconnection.

Other systems, methods, features and advantages will be, or will become, apparent to one with skill in the art upon examination of the following figures and detailed description. Nothing in this section should be taken as a limitation on those claims. Further aspects and advantages are discussed below in conjunction with the embodiments.

### BRIEF DESCRIPTION OF THE DRAWING

FIG. 1 is a cross-sectional view showing a metal interconnection structure of a semiconductor device according to an embodiment of the present invention.

FIGS. 2-5 are cross-sectional views illustrating a method for manufacturing a metal interconnection structure of a semiconductor device according to an embodiment of the present invention.

### DETAILED DESCRIPTION

Hereinafter, a metal interconnection structure of a semiconductor device and a method for manufacturing the same according to embodiments of the present invention will be described in detail with respect to accompanying drawings. It will be apparent to those skilled in the art that the present invention is not limited to the following embodiments, and various modifications and variations can be realized within the scope of the appended claims and their equivalents. In the accompanying drawings, sizes of structures such as the first capping layer, a barrier layer, an adhesion layer, a silicon-oxy-carbide layer, the second capping layer, and upper and lower metal interconnections are enlarged for illustration of the present invention. In this disclosure, when it is described that the structures such as the first capping layer, the barrier layer, the adhesion layer, the silicon-oxy-carbide layer, the second capping layer, and the upper and lower metal interconnections are formed “on”, “on an upper surface”, “below” or “on a lower surface”, it means that they are directly or indirectly formed on the upper surface or the lower surface of the structures such as the first capping layer, the barrier layer, the adhesion layer, the silicon-oxy-carbide layer, the second capping layer, and the upper and lower metal interconnections, or other structures such as the first capping layer, a barrier layer, an adhesion layer, a silicon-oxy-carbide layer, a second capping layer, and upper and lower metal interconnections.

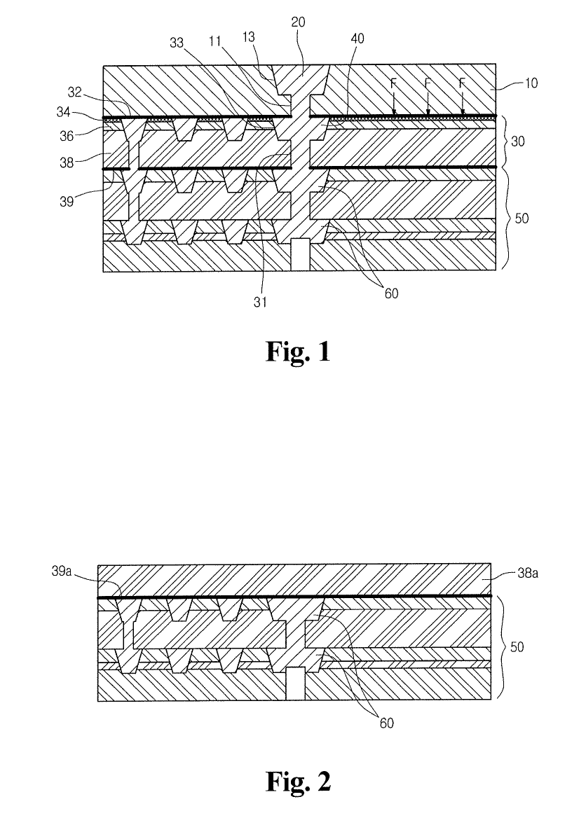

FIG. 1 is a cross-sectional view showing a metal interconnection structure of a semiconductor device according to an embodiment.

Referring to FIG. 1, the metal interconnection structure of the semiconductor device includes an upper interlayer dielectric layer pattern 10, an upper metal interconnection 20, a lower interlayer dielectric layer pattern 30, and a lower metal interconnection 40. Reference numbers 50 and 60 represent a base interlayer dielectric layer pattern and a base metal interconnection formed on the base interlayer dielectric layer, respectively.

According to the present embodiment, the upper interlayer dielectric layer pattern 10 includes fluorine (F). For example, the upper interlayer dielectric layer pattern 10 can be a fluorine silicate glass (FSG) layer pattern induced to have a low dielectric constant by doping an undoped silicate glass (USG) layer with fluorine (F).

The upper interlayer dielectric layer pattern 10 can have a dual damascene pattern such that an upper metal interconnection 20 is formed. In detail, a dual damascene pattern of the upper interlayer dielectric layer pattern includes a contact hole 11 passing through the upper interlayer dielectric layer pattern 10 and a trench 13 formed by, for example, expanding a portion of the contact hole 11.

The upper metal interconnection 20 is formed inside the dual damascene pattern formed in the upper interlayer dielectric layer pattern 10. The upper metal interconnection 20 can be formed of metal including copper (Cu).

The lower interlayer dielectric layer pattern 30 is provided below the upper interlayer dielectric layer pattern 10. According to the present embodiment, the lower interlayer dielectric layer pattern 30 includes a barrier layer pattern 34, an adhesion layer pattern 36, and a silicon-oxy-carbide (SiOC) layer pattern 38. Here, the lower interlayer dielectric layer pattern 30 further includes an upper capping layer pattern 32 and a lower capping layer pattern 39.

The upper capping layer pattern 32 directly makes contact with the upper interlayer dielectric layer pattern 10 to inhibit fluorine (F), which has a high migration property, from penetrating into the lower interlayer dielectric layer pattern 30 from the upper interlayer dielectric layer pattern 10. The upper capping layer pattern 32 can be formed between the upper interlayer dielectric layer pattern 10 and the lower interlayer dielectric layer pattern 30.

The barrier layer pattern 34 is provided at a lower portion of the upper capping layer pattern 32. The barrier layer pattern 34 blocks fluorine (F) moving to the lower interlayer dielectric layer pattern 30 from the upper interlayer dielectric layer pattern 10 through a pin hole, which may form in the upper capping layer pattern 32. The barrier layer pattern 34 can inhibit the fluorine (F) from penetrating into the lower interlayer dielectric layer pattern 30 from the upper interlayer dielectric layer pattern 10.

The barrier layer pattern 34 can include various materials if they can chemically react with fluorine (F). For example, in one embodiment, the barrier layer pattern 34 includes boron (B). In detail, the barrier layer pattern 34, according to a specific embodiment, can be a boron-doped silicate glass (BSG) layer pattern doped with boron (B).

The boron (B) included in the barrier layer pattern 34 chemically reacts with fluorine (F) introduced through a pin hole of the upper capping layer pattern 32 to become boron tri-fluoride (BF₃), so that the fluorine (F) is captured in the barrier layer pattern 34. Accordingly, the fluorine (F) can be blocked from being introduced into the silicon-oxy-carbide (SiOC) layer pattern 38, which is described later, through the pin hole, thereby inhibiting fluorinated silicon oxide (SiOF) having a high dielectric constant from being formed in the silicon-oxy-carbide (SiOC) layer pattern 38.

In a preferred embodiment, the thickness of the barrier layer pattern 34 is in the range about 40% to about 60% of the thickness of an adhesion layer 36 in order to inhibit the fluorine (F) from being diffused. When the barrier pattern 34 is thinner than about 40% to about 60% of the thickness of the adhesion layer 36, the capability of capturing the fluorine (F) may be reduced. When the barrier layer pattern 34 is thicker than about 40% to about 60% of the thickness of the adhesion layer pattern 36, the fluorine (F) may move into the silicon-oxy-carbide (SiOC) layer pattern 34. In one embodiment, the thickness of the adhesion layer pattern 36 can be in the range of about 1,600 Å to about 1,800 Å. Therefore, in a specific embodiment, the adhesion pattern 36 has the thickness of about 1,700 Å, and the barrier layer pattern 34 has the thickness of about 850 Å corresponding to a half of the thickness of the adhesion layer pattern 36.

The adhesion layer pattern 36 is disposed below the barrier layer pattern 34. According to an embodiment, the adhesion layer pattern 36 can be an undoped silicate glass layer (USG) pattern.

Since the adhesion between the barrier layer pattern 34 doped with boron (B) and the silicon-oxy-carbide (SiOC) layer pattern 38 is inferior, the barrier layer pattern 34 and the silicon-oxy-carbide (SiOC) pattern 38, which directly make contact with each other, may be mutually delaminated. Since an adhesion layer pattern 36 can be interposed between the barrier layer pattern 34 and the silicon-oxy-carbide (SiOC) layer pattern 38, the delamination of the barrier layer pattern 34 and the silicon-oxy-carbide (SiOC) layer pattern 38 can be inhibited.

The silicon-oxy-carbide (SiOC) layer pattern 38 (also referred to as BLACK DIAMOND) includes silicon-oxy-carbide (SiOC) having a low dielectric constant, which is capable of reducing delay or distortion in signals applied to the lower metal interconnection 40.

The second capping layer pattern 39 can be provided below the silicon-oxy-carbide (SiOC) layer pattern 38.

According to an embodiment, the lower interlayer dielectric layer pattern 30 can have a dual damascene pattern to form a lower metal interconnection 40. In detail, a dual damascene pattern of the lower interlayer dielectric layer pattern 30 includes a contact hole 31 passing through the lower interlayer dielectric layer pattern 30 and a trench 33 formed by expanding a portion of the contact hole 31.

The lower metal interconnection 40 is formed inside the dual damascene pattern formed in the lower interlayer dielectric layer pattern 30. The lower metal interconnection 40 can include copper (Cu).

In a further embodiment, at least one base interlayer dielectric layer pattern 50 can be additionally formed below the lower interlayer dielectric layer pattern 30, and a base metal interconnection 60 can be formed in each base interlayer dielectric layer pattern 50.

FIG. 2 is a cross-sectional view showing a method for manufacturing a metal interconnection structure of a semiconductor device according to an embodiment.

Referring to FIG. 2, a base interlayer dielectric layer pattern 50 can be formed on a semiconductor substrate such as a wafer, and a base metal interconnection 60 can be formed on the base interlayer dielectric layer pattern. According to an embodiment, a dual damascene pattern can be formed in the base interlayer dielectric layer pattern 50, and the base metal interconnection 60 is formed inside the dual damascene pattern formed in the base interlayer dielectric layer pattern 50.

Subsequently, a lower capping layer 39a is formed on a top surface of the base interlayer dielectric layer pattern 50, and then a silicon-oxy-carbide (SiOC) layer 38a is formed on a top surface of the lower capping layer 39a. In one embodiment, the lower capping layer 39a and the silicon-oxy-carbide (SiOC) layer 38a are formed through a chemical vapor deposition (CVD) process.

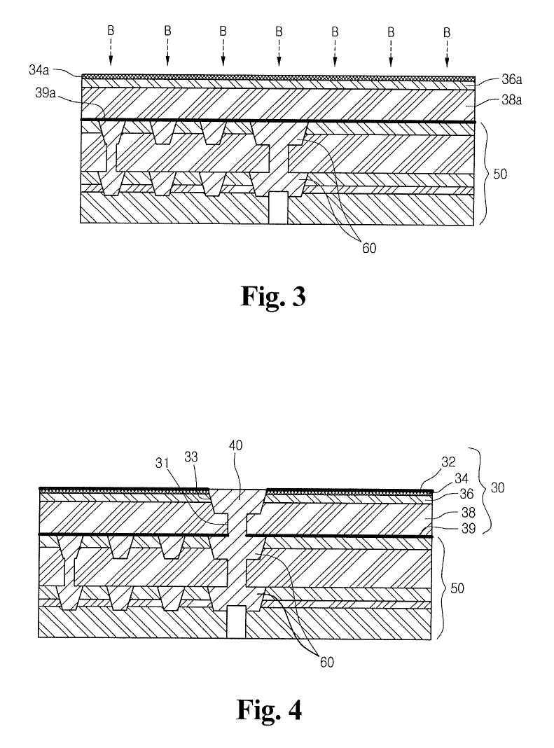

FIG. 3 is a cross-sectional view showing an adhesion layer formed on the silicon-oxy-carbide (SiOC) layer shown in FIG. 2.

Referring to FIG. 3, an adhesion layer 36a is formed on the silicon-oxy-carbide (SiOC) layer 38a. The adhesion layer 36a can be an USG layer formed through a CVD process. After the adhesion layer 36a is formed on the silicon-oxy-carbide (SiOC) layer 38a, the adhesion layer 36a can be doped with boron (B). The boron (B) can be implanted through an ion implantation process. According to an embodiment, about 2.1×10¹³ to about 2.5×10¹³ boron ions/cm² are implanted into the adhesion layer 36a with an implantation energy in the range of 40 KeV to 60 KeV.

As the adhesion layer 36a is doped with boron (B), the barrier layer 34a is formed on the top surface of the adhesion layer 36a. Thus, the lower interlayer dielectric layer 30a is formed. According to an embodiment, when the adhesion layer 36a is USG, the barrier layer 34a is boron-doped silicate glass (BSG) including boron (B).

In an embodiment, the final thickness of the adhesion layer 36a measured from the top surface of the silicon-oxy-carbide (SiOC) layer 38a can be in the range of about 1,600 Å to about 1,800 Å. In one embodiment, the adhesion layer 36a has the thickness of about 1,700 Å and the barrier layer 34a has a thickness of about 850 Å.

In an alternative embodiment, the barrier layer 34a can be formed through a CVD process. For example, the adhesion layer 36a can be an USG layer, and the barrier layer 34a can be a BSG layer formed on the USG layer through the CVD process.

FIG. 4 is a cross-sectional view showing a lower interlayer dielectric layer pattern having the lower metal interconnection formed by patterning the lower interlayer dielectric layer shown in FIG. 3.

After the lower interlayer dielectric layer 30 including the silicon-oxy-carbide (SiOC) layer 38a, the adhesion layer 36a, and the barrier layer 34a is formed, the lower interlayer dielectric layer 30 is patterned twice, thereby forming a dual damascene pattern in the lower interlayer dielectric layer 30. Then, after forming a contact hole 31 passing through the lower interlayer dielectric layer 30 in the dual damascene pattern, a trench 33 is formed by expanding the upper portion of the contact hole 31. Thus, a dual damascene pattern is formed, and the silicon-oxy-carbide (SiOC) layer 38a, the adhesion layer 36a, and the barrier layer 34a become the silicon-oxy-carbide (SiOC) layer pattern 38, the adhesion layer pattern 36, and the barrier layer pattern 34, respectively.

After the dual damascene pattern having the trench 33 and the contact hole 31 is formed, the lower metal interconnection 40 including copper (Cu) is formed on the dual damascene pattern.

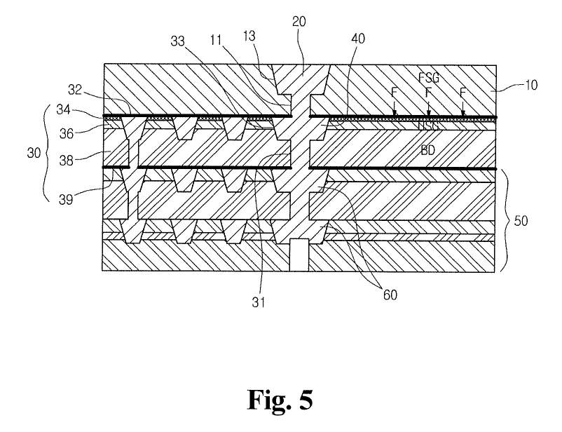

FIG. 5 is a cross-sectional view showing an upper interlayer dielectric layer and upper metal interconnection formed on the lower interlayer dielectric layer and the lower metal interconnection shown in FIG. 4.

Referring to FIG. 5, after the lower interlayer dielectric layer 30 is formed, an upper capping layer 32 can be formed on the lower interlayer dielectric layer 30. After the upper capping layer 32 is formed, a fluorine doped silicate glass (FSG), in which fluorine (F) is doped, can be formed on the entire surface of the capping layer 32, thereby forming the upper interlayer dielectric layer 10.

Subsequently, the upper interlayer dielectric layer (not shown) can be patterned twice to form a dual damascene pattern in the upper interlayer dielectric layer. In such an embodiment, after forming a contact hole 11 passing through the upper interlayer dielectric layer in the dual damascene pattern, a trench 13 is formed by expanding the upper portion of the contact hole 11. Thus, the dual damascene pattern is formed in the upper interlayer dielectric layer. Then, the upper metal interconnection 20 is formed on the dual damascene pattern of the upper interlayer dielectric layer 10.

According to embodiments of the present invention, even if the fluorine (F) having a high migration property included in the upper interlayer dielectric layer pattern 10 moves to the barrier layer pattern 34 through the upper capping layer pattern 32, the fluorine (F) moved to the barrier layer pattern 34 can combine with the boron (B) included in the barrier layer pattern 34 so that boron tri-fluoride (BF₃) is formed. Accordingly, the fluorine (F) does not penetrate into the silicon-oxy-carbide (SiOC) layer pattern (36) in the lower portion of the barrier layer pattern 34, thereby reducing delay or distortion of signals applied to the upper metal interconnection 20 and the lower metal interconnection 40.

As described above, in order to prevent fluorine (F), which is included in one of interlayer dielectric layers formed between a plurality of stacked metal interconnections, from penetrating into a neighboring interlayer dielectric layer, a barrier layer including boron (B), which can combine with the fluorine (F), is formed between the interlayer dielectric layers, thereby inhibiting the fluorine (F) from being diffused. Accordingly, the increase of the dielectric constant of the interlayer dielectric layer can be inhibited.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive. The above disclosed subject matter is to be considered illustrative, and not restrictive, and the appended claims are intended to cover all such modifications, enhancements, and other embodiments, which fall within the true spirit and scope of the present invention.

What is claimed is:

1. A metal interconnection structure of a semiconductor device, the metal interconnection structure comprising:
an upper interlayer dielectric layer pattern comprising fluorine (F);
a lower interlayer dielectric layer pattern comprising:
a barrier layer pattern to inhibit diffusion of fluorine (F) provided below the upper interlayer dielectric layer pattern,
an adhesion layer pattern below the barrier layer pattern, and
a silicon-oxy-carbide (SiOC) layer pattern below the adhesion layer pattern; and
an upper metal interconnection formed on the upper interlayer dielectric layer pattern and electrically connected to a lower metal interconnection formed on the lower interlayer dielectric layer pattern.

2. The metal interconnection structure according to claim 1, wherein the upper interlayer dielectric layer pattern comprises fluorine silicate glass (FSG).

3. The metal interconnection structure according to claim 1, wherein the barrier layer pattern comprises boron doped silicate glass (BSG).

4. The metal interconnection structure according to claim 1, wherein a thickness of the barrier layer pattern is about 40% to about 60% a thickness of the adhesion layer pattern.

5. The metal interconnection structure according to claim 4, wherein the thickness of the adhesion layer pattern is in a range of about 1600 Å to about 1800 Å.

6. The metal interconnection structure according to claim 1, wherein the adhesion layer pattern comprises updoped silicate glass (USG).

7. The metal interconnection structure according to claim 1, wherein the upper metal interconnection comprises copper (Cu).

8. The metal interconnection structure according to claim 1, wherein the lower metal interconnection comprises copper (Cu).

9. The metal interconnection structure according to claim 1, wherein the lower interlayer dielectric layer pattern further comprises at least one of an upper capping layer pattern and a lower capping layer pattern, wherein the upper capping layer pattern directly makes contact with the upper interlayer dielectric layer pattern.

10. A method for manufacturing a metal interconnection structure of a semiconductor device, the method comprising:
forming a lower interlayer dielectric layer pattern, wherein forming the lower interlayer dielectric layer pattern comprises:
forming a silicon-oxy-carbide (SiOC) layer,
forming an adhesion layer on the silicon-oxy-carbide (SiOC) layer, and
forming a barrier layer comprising boron (B) on the adhesion layer;
forming a lower metal interconnection on the lower interlayer dielectric layer pattern;
forming an upper interlayer dielectric layer pattern on the lower interlayer dielectric layer pattern including the lower metal interconnection; and
forming an upper metal interconnection on the upper interlayer dielectric layer pattern and electrically connected to the lower metal interconnection.

11. The method according to claim 10, wherein the adhesion layer comprises an undoped silicate glass (USG) layer.

12. The method according to claim 10, wherein forming the barrier layer comprising boron (B) comprises implanting about 2.1×10¹³ to about 2.5×10¹³ boron ions/cm² into the adhesion layer with an implantation energy in a range of 40 KeV to 60 KeV.

13. The method according to claim 10, wherein forming the silicon-oxy-carbide (SiOC) layer comprises performing a chemical vapor deposition (CVD) process.

14. The method according to claim 10, wherein the upper interlayer dielectric layer pattern comprises fluorine (F).

15. The method according to claim 14, wherein the barrier layer comprising boron (B) inhibits diffusion of the fluorine (F).

16. The method according to claim 10, wherein the upper metal interconnection comprises copper (Cu).

17. The method according to claim 10, wherein the lower metal interconnection comprises copper (Cu).

18. The method according to claim 10, further comprising forming a lower capping layer covering a lower structure before forming the SiOC layer, wherein the lower metal layer electrically connects to the lower structure.

19. The method according to claim 10, further comprising forming an upper capping layer on a top surface of the barrier layer, wherein the upper metal interconnection connects with the lower metal interconnection by passing through the upper capping layer.
